(19) United States
(12) Patent Application Publication
(10) Pub. No.: US 2005/0226719 A1
(43) Pub. Date: Oct. 13, 2005

(54) Built-up guide flow fan device

(76) Inventor: Sung-Wei Sun, Taipei (TW)

Correspondence Address: Ann Tsai, Suite137, PmB 174, 931 West 75th Street, Naperville, IL, 60565, US

(21) Appl. No.: 10/819,219

(22) Filed: Apr. 7, 2004

(51) Int. Cl. F03B 1/00

(52) U.S. Cl. 415/193

(57) ABSTRACT

A built-up guide flow fan device includes a first guide flow fan and a second guide flow fan. The first guide flow fan provides cooling blades and a guide flow part and the guide flow part is composed of guide flow blades, which are disposed next to the air outlet of the first guide flow fan. The second guide flow fan is attached to the first guide flow fan with the air outlet of the first guide flow fan being mounted to the air inlet of the second guide flow fan. The second guide flow fan provides cooling blades and a guide flow part too and the guide flow part is composed of a plurality of guide flow blades, which are disposed next to the air inlet of the second guide flow fan. The guide flow blades of the first guide flow fan and the guide flow blades of the second guide flow fan butt to each other tightly to form guide flow passages. Air pressure and flow rate of air flow blown by the built-up guide flow fan can be increased effectively.

### BACKGROUND OF THE INVENTION

1. Field of the Invention

The present invention relates to a built-up guide flow fan device and particularly to guide flow fan device, which is detachably composed of a first guide flow fan and a second guide flow fan with the guide flow parts thereof being butted tightly, for increasing air pressure and flow rate of the air flow.

2. Brief Description of Related Art

Due to fast development of the electronic component, the size thereof is getting smaller and the operation speed is getting faster. But, the heat dissipation becomes a problem along with high speed operation. It often results in abnormal running of the electronic component and even damaged electronic component

Usually, the cooling fan is used for removing heat generated by the electronic component and in order to control the output air direction, the cooling fan is provided with a guide flow part as a guide flow fan so as to perform an effect of concentrating the air flow. However, the preceding guide flow fan is involved in deficiency of insufficient flow rate. Referring to FIGS. 1 to 3, the preceding guide flow fan basically includes a first guide flow fan 11 and a second guide flow fan 12. The first guide flow fan 11 provides cooling blades 111 and a guide flow part 112. The guide flow part 112 is composed of a plurality of guide flow blades 112a, which are disposed at the air outlet side 113. The second guide flow fan 12 is provided with cooling blades 121 and a guide flow part 122. The guide flow part 122 is composed of a plurality of guide flow blades 122a and is disposed at the air inlet side 123a of the second guide flow fan 12. The air outlet 113 of the first guide flow fan 11 is mounted at the air inlet 123 of the second guide flow 12. But, the guide flow blades 112a is arranged to contact with the guide flow blades 122a in a way of alternately positioning to each other. In this way, the integral air flow contrarily becomes disorder to decrease air pressure and flow rate instead of increasing the air pressure and flow rate.

Besides, the Taiwanese Patent Publication No. 490131, entitled “RADIATOR WITH COMPLEX LAYER BLADES”, provides an outer casing with an inner chamber for receiving a lower base. It is characterized in that a plurality layers of fan blades are provided in the outer casing and the fan blade layers includes static blade sets and dynamic blade sets, which are arranged at upper and lower sides of the static blades. The dynamic blades are utilized to drag a deal of air flow for achieving better effect of heat removal. But, the whole radiator has to be renewed once one of the dynamic blades is damaged before original effect of heat dissipation being able to be obtained. It leads to expend more and lower running efficiency of the computer.

### SUMMARY OF THE INVENTION

An object of the present invention is to provide a built-up guide flow fan device, which can increase air pressure and flow rate effectively.

Another object of the present invention is to provide a built-up guide flow fan device, which allows guide flow fans thereof being replaced easily.

A further object of the present invention is to provide a built-up guide flow fan device, which is possible to allow more guide flow fans thereof being attached to each other in series.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of a conventional built-up guide flow fan;

FIG. 2 is an assembled perspective view of the built-up guide flow fan shown in FIG. 1;

FIG. 3 is a sectional view along line 3-3 shown in FIG. 2;

FIG. 4 is an exploded perspective view of the first embodiment according to the present invention;

FIG. 5 is an assembled perspective view of the first embodiment shown in FIG. 4;

FIG. 6 is a sectional view along line 6-6 shown in FIG. 5;

FIG. 7 is a sectional view of the first embodiment according to the present invention;

FIG. 8 is an exploded perspective view of the second embodiment according to the present invention;

FIG. 9 is an assembled perspective view of the second embodiment according to the present invention; and

FIG. 10 is a sectional view along line 10-10 shown in FIG. 9.

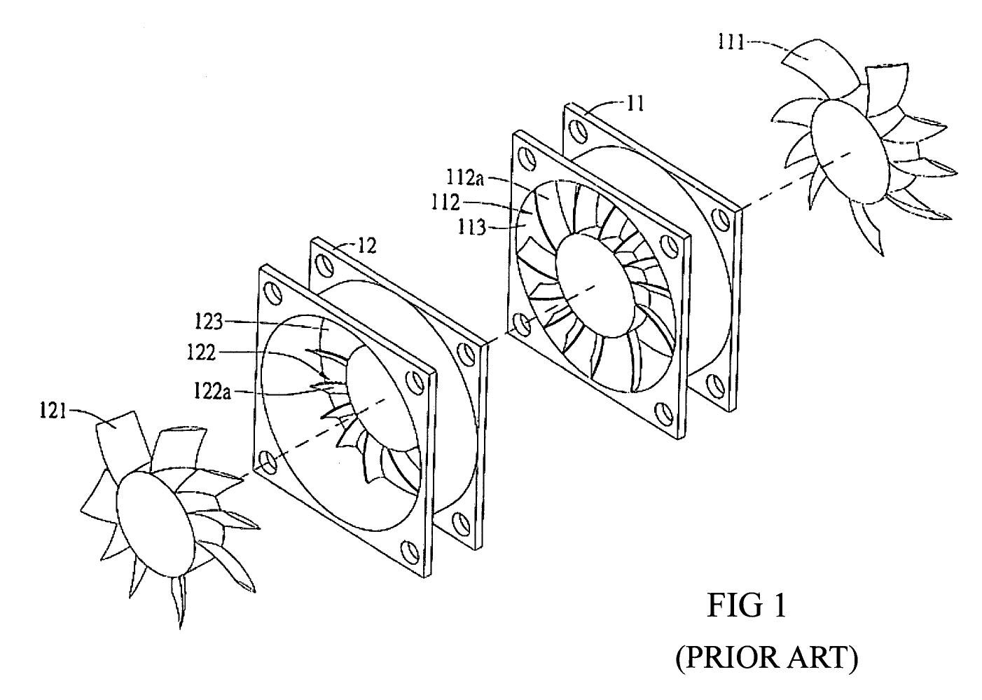

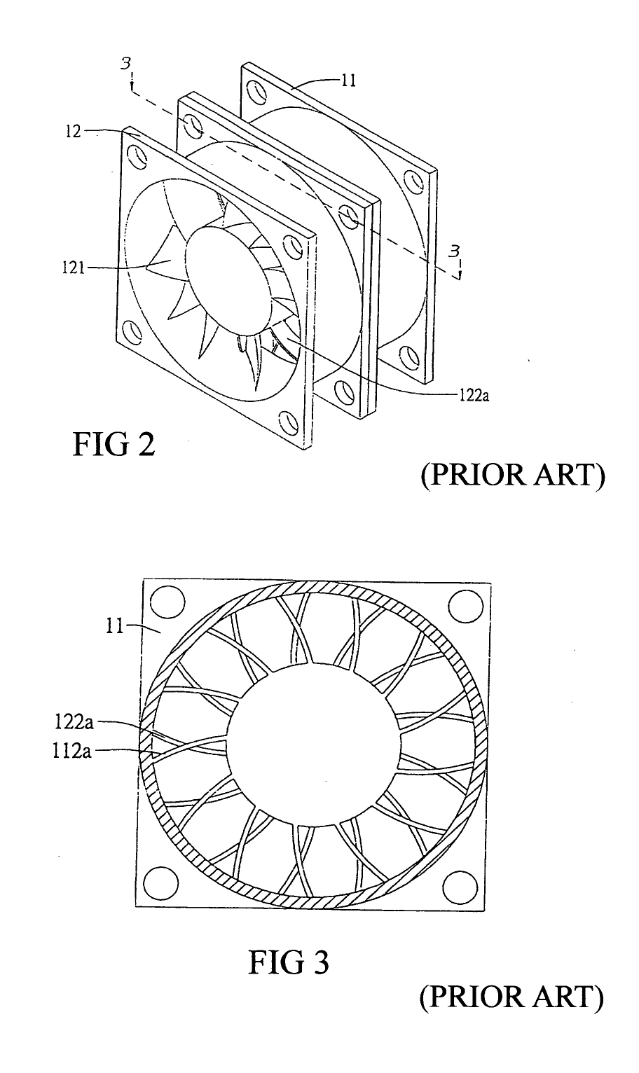

### DETAILED DESCRIPTION OF THE PREFERRED EMBODIMENTS

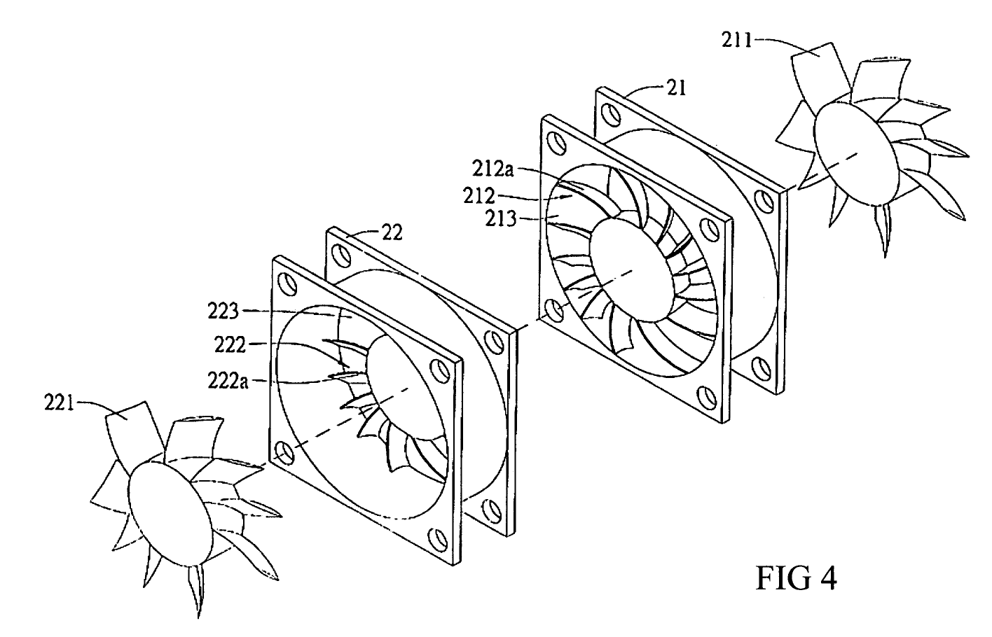

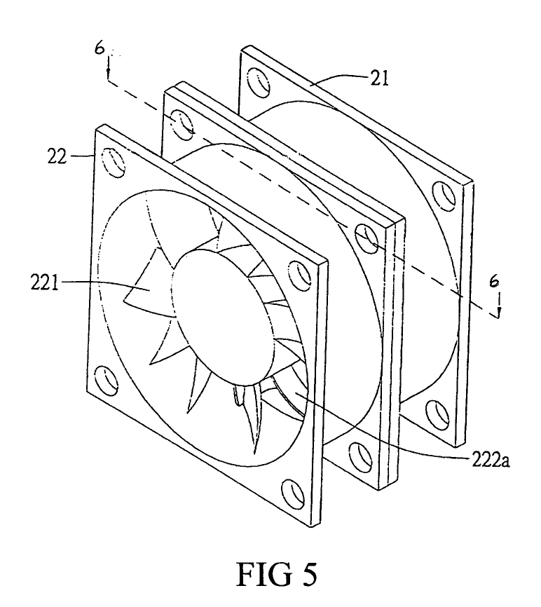

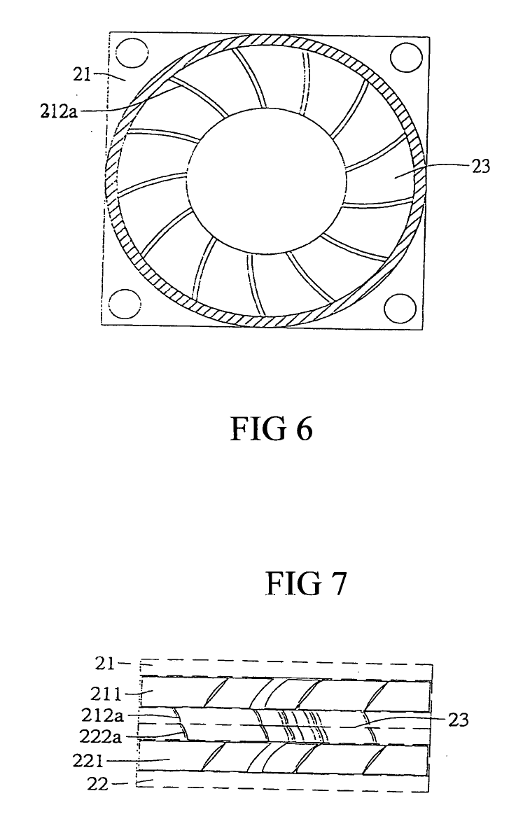

Referring to FIGS. 4 to 7, a built-up guide flow fan device of the first embodiment according to the present invention is composed of a first guide flow fan 21 and a second guide flow fan 22. The first guide flow fan 21 has cooling blades 211 and a guide flow part 212. The guide flow part 212 is provided with a plurality of 212a and disposed at the air outlet 213 of the first guide flow fan 21. The second guide flow fan 22 has cooling blades 221 and guide flow part 222. The guide flow part 222 is disposed at the air inlet 223 of the second guide flow fan 22.

The air outlet 213 of the first guide flow fan 21 is disposed at the air inlet 223 of the second guide flow fan 22 and the guide flow blades 212a of guide flow part 212 in the first guide flow fan 21 and the guide flow blades 222a of the guide flow part 222 in the second guide flow fan 22 are butted to each other tightly to form a plurality of guide flow passages 23. The guide flow passages 23 allow the air flow generated by the first guide flow fan 21 being blown toward the center of the second guide flow fan 22 or being blown toward outer sides of the cooling blades 221 in the second guide flow fan 22 based on the need of heat dissipation. Once the first guide flow fan 21 is powered on and actuates the cooling blades 211 to rotate, it is capable of increasing air pressure of the air flow before entering the second guide flow fan 22. Further, the air flow generated by the first guide flow fan 21 can be concentrated and increase the air pressure thereof after passing through the guide flow passages 23 and before entering the second guide flow fan 22. Hence, integral output of the air flow blown with the built-up guide flow fan of the present invention can be provided with increased air pressure and flow rate after the air flow being blown outward with the second guide flow fan 22.

Furthermore, in case of one of the guide flow fans being damaged in the built-up guide flow fan of the present invention, the damaged one can be replaced immediately instead of the entire set of the fan being replaced as the conventional fan does. Hence, the guide flow fan of the present invention is convenient and costless.

In addition, the built-up guide flow fan device of the present invention can be set up in series to increase the air pressure and the air flow required by the electronic components.

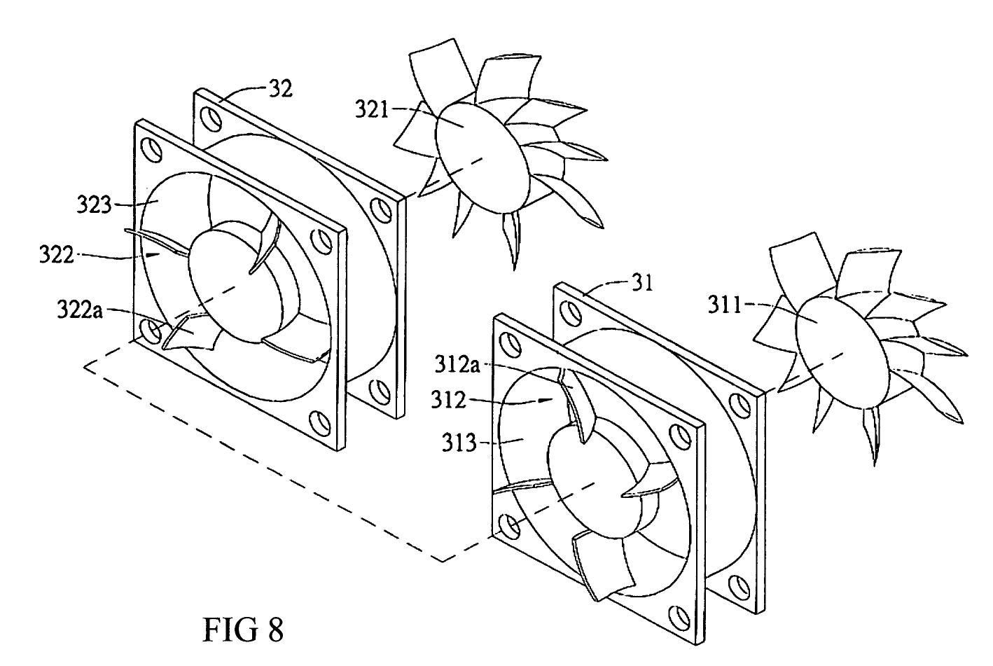

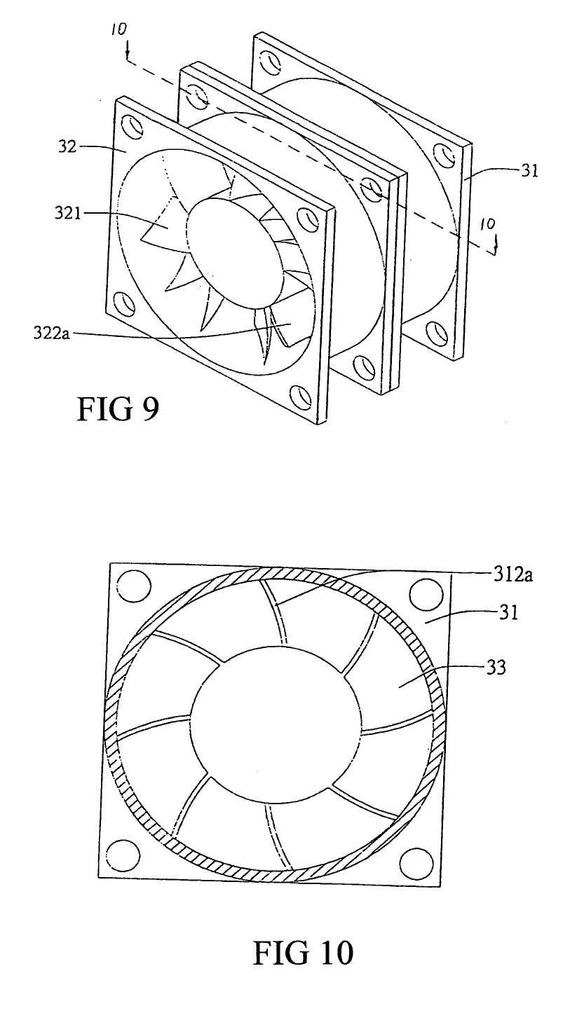

Referring to FIGS. 8 to 10, the second embodiment of the present invention is illustrated. The built-up guide flow fan device according to the present invention has a fist guide fan 31 and a second guide fan 32. The first guide flow fan 31 has cooling blades 311 and a guide flow part 312. The guide flow part 312 is provided with a plurality of guide flow blades 212a and disposed at the air outlet 313 of the first guide flow fan 31 in a way of jutting out from the first guide flow fan 31. The second guide flow fan 32 has cooling blades 321 and a guide flow part 322. The guide flow part 322 has a plurality of guide flow blades 322a and is disposed at the air inlet 323 of the second guide flow fan 32 in a way of jutting out from the second guide flow fan 32. Further, The cooling blades 312a and 322a are arranged in a way of being disposed in a way of positioning alternately to each other.

The air outlet 313 of the first guide flow fan 31 is located at the air inlet 323 of the second guide flow fan 32. Due to the cooling blades 312a and 322a being disposed in a way of positioning alternately to each other and the cooling blades 312a and 322a jutting out of the first guide flow fan 31 and the second guide flow fan 32 respectively, the cooling blades 312a extends into the second guide flow fan 32 and the cooling blades 322a extends into the first guide flow fan 31 such that the guide flow blades 312a and 322a form guide flow passages 33 between the first guide flow fan 31 and the second guide flow fan 32. Hence, integral output of the air flow can be provided with increased air pressure and flow rate as done in the first embodiment. Further, in case of one of the guide flow fans being damaged in the built-up guide flow fan device of the present invention, the damaged one can be replaced immediately instead of the entire set of the built-up fan being replaced as the conventional fan does. Hence, the built-up guide flow fan device of the present invention is convenient and costless.

While the invention has been described with referencing to preferred embodiments thereof, it is to be understood that modifications or variations may be easily made without departing from the spirit of this invention, which is defined by the appended claims.

1. A built-up guide flow fan device, comprising:
a first guide flow fan with a first air inlet and a first air outlet, providing first cooling blades and a first guide flow part, the first guide flow part being composed of a plurality of first guide flow blades, which are disposed next to the first air outlet; and
a second guide flow fan with a second air inlet and a second air outlet, being attached to the first guide flow fan with the first air outlet being mounted to the second air inlet, providing second cooling blades and a second guide flow part, the second guide flow part being composed of a plurality of second guide flow blades, which are disposed next to the second air inlet;
wherein, the first guide flow blades and the second guide flow blades butt to each other tightly to form a plurality of guide flow passages;
whereby, air pressure and flow rate of air flow blown by the built-up guide flow fan can be increased effectively.

2. The built-up guide flow fan device as defined in claim 1, wherein multiple sets of the first guide flow fan and the second guide flow fan assembly can be built up in series.

3. A built-up guide flow fan device, comprising
a first guide flow fan with a first air inlet and a first air outlet, providing first cooling blades and a first guide flow part, the first guide flow part being composed of a plurality of first guide flow blades, which are disposed next to the first air outlet in a way of jutting outward from the first guide flow fan; and
a second guide flow fan with a second air inlet and a second air outlet, being attached to the first guide flow fan with the first air outlet being mounted to the second air inlet, providing second cooling blades and a second guide flow part, the second guide flow part being composed of a plurality of second guide flow blades, which are disposed next to the second air inlet in a way of jutting outward from the second guide flow fan;
wherein, the first guide flow blades and the second guide flow blades are arranged in a way of positioning alternately to each other sequentially and extend into the second guide flow fan and the first guide flow fan respectively to form a plurality of guide flow passages;
whereby, air pressure and flow rate of air flow blown by the built-up guide flow fan can be increased effectively.

4. The built-up guide flow fan device as defined in claim 3, wherein multiple sets of the first guide flow fan and the second guide flow fan assembly can be built up in series.
